(19) United States
(12) Patent Application Publication
(10) Pub. No.: US 2012/0300422 A1
(43) Pub. Date: Nov. 29, 2012

(54) ENCLOSURE AND CABLE CLIP

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/166,784

(22) Filed: Jun. 22, 2011

(30) Foreign Application Priority Data
May 23, 2011 (CN) 201110133537.1

(51) Int. Cl. H05K 5/00; F16L 3/22

(52) U.S. Cl. 361/759; 248/68.1

(57) ABSTRACT

An enclosure includes a bottom plate, a circuit board, and a cable clip. A number of mounting posts extend from the bottom plate. Each mounting post axially defines a mounting hole. The cable clip includes a main body, a mounting portion extending from a first end of the main body, and a clipping portion extending from a second end of the main body to bind cables. The cable clip defines a first through hole, for a corresponding one mounting post extending through. The circuit board defines a number of second through holes. The circuit board is supported on the mounting posts, with the second through holes aligning with the mounting holes. Fasteners extend through the second through holes to engage in the mounting holes to mount the circuit board to the bottom plate. The mounting portion is clamped between the circuit board and the bottom plate.

### BACKGROUND

1. Technical Field

The present disclosure relates to a cable clip and an electronic enclosure with the cable clips.

2. Description of Related Art

Cable clips are used to bind cables in computers or servers. However, normally, the cable clips are glued to enclosures of the computers or servers, which makes them inconvenient to be removed from the enclosures.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an enclosure, the enclosure includes a cable clip.

FIG. 2 and FIG. 3 are enlarged views of the cable clip of FIG. 1, but viewed from different perspectives.

FIG. 4 and FIG. 5 are assembled, isometric views of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

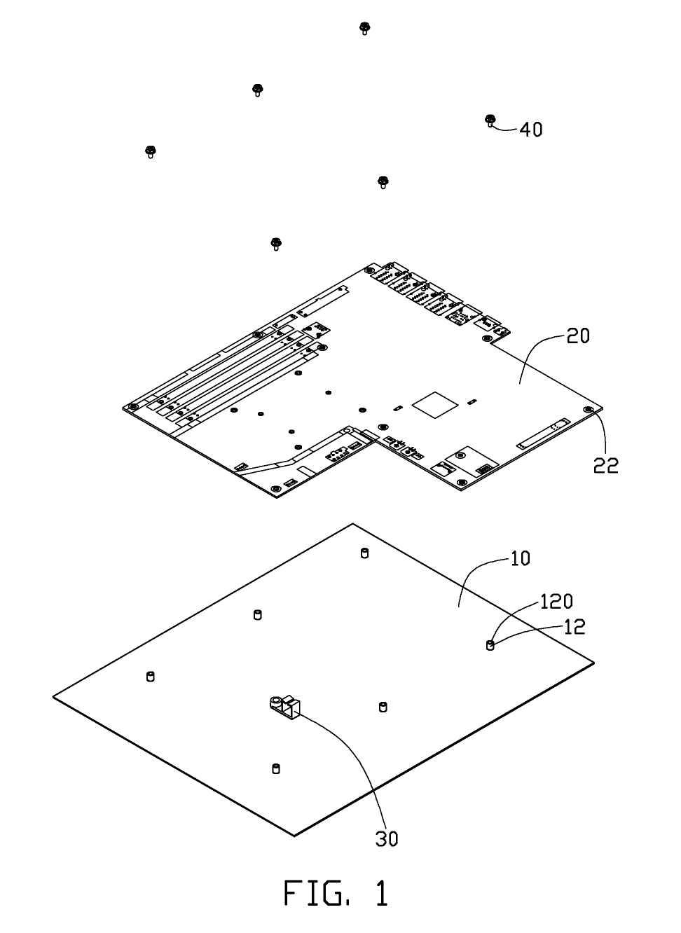

Referring to FIG. 1, an exemplary embodiment of an enclosure includes a bottom plate 10, a circuit board 20, a cable clip 30, and a plurality of fasteners 40. In this embodiment, each fastener 40 is a screw.

The bottom plate 10 includes a plurality of mounting posts 12 substantially perpendicularly extending up from the bottom plate 10. Each mounting post 12 axially defines a mounting hole 120. In this embodiment, the mounting hole 120 is a threaded hole.

The circuit board 20 defines a plurality of though holes 22 corresponding to the mounting holes 120.

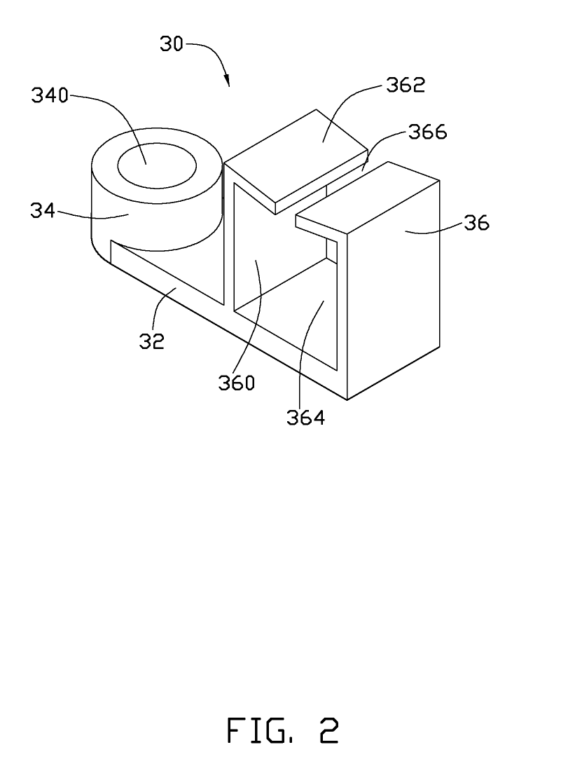

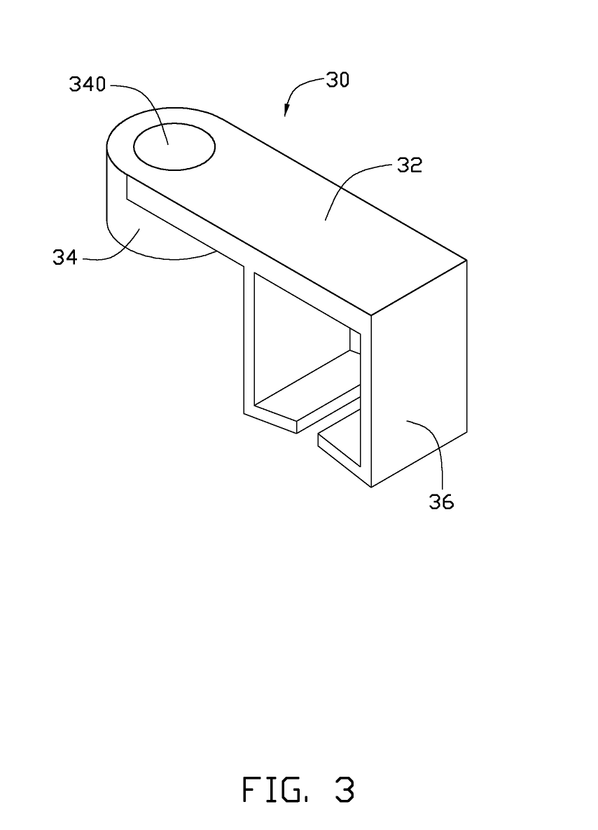

Referring to FIGS. 2 and 3, the cable clip 30 includes a substantially rectangular main body 32, a substantially cylinder-shaped mounting portion 34 perpendicularly extending up from a first end of the main body 32, and a clipping portion 36 formed on a second end of the main body 32 opposite to the first end. The sum of the thickness of the main body 32 and the height of the mounting portion 34 is substantially equal to the height of each mounting post 12. The mounting portion 34 axially defines a through hole 340, extending through the main body 32. The clipping portion 36 includes two parallel first limiting pieces 360 substantially perpendicularly extending up from the second end of the main body 32, and two second limiting pieces 362 each slantingly extending down from a top of the corresponding first limiting piece 360 toward the other first limiting piece 360. A clipping space 364 is bounded by the first limiting pieces 360 and the second limiting pieces 362. A cable channel 366 is defined between the second limiting pieces 362, communicating with the clipping space 364. The clipping space 364 receives the cables 50. The cable channel 366 allows the cables 50 to enter the clipping space 364.

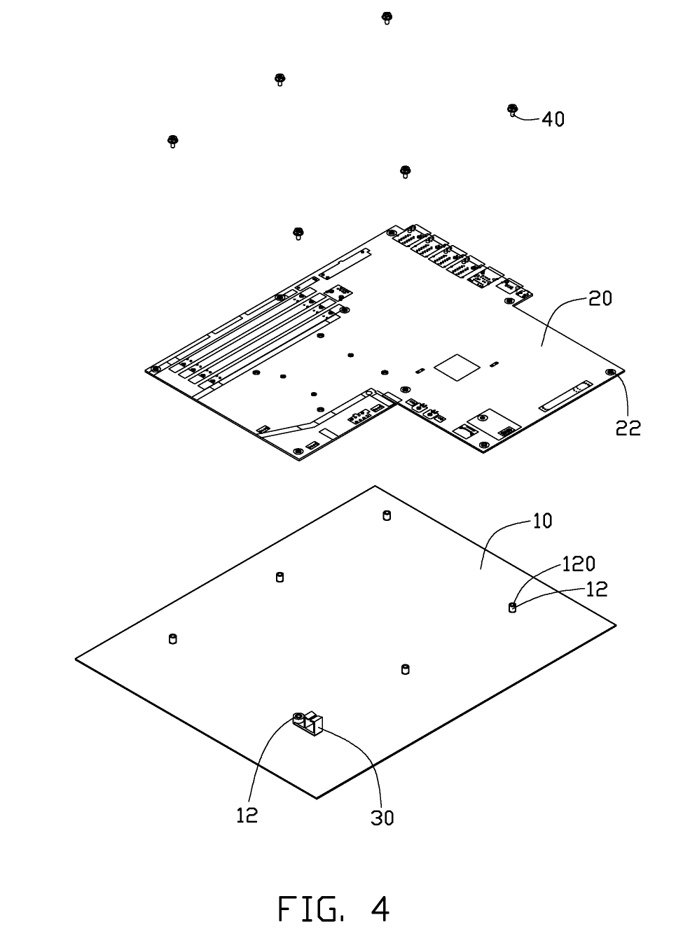

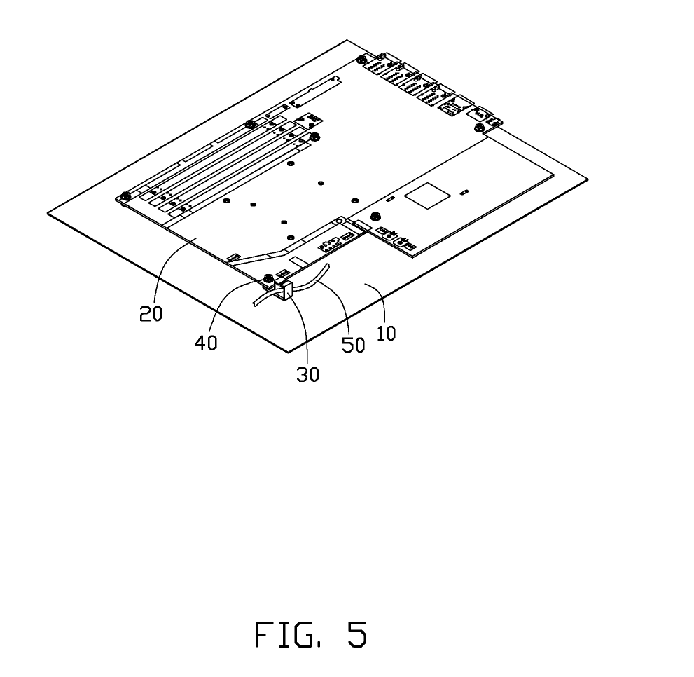

Referring to FIGS. 4 and 5, in assembly, one of the mounting posts 12 adjacent to an edge of the circuit board 20 extends through the through hole 340 of the cable clip 30, to allow the cable clip 30 to fit about the mounting post 12. The main body 32 contacts with the bottom plate 10. The circuit board 20 is positioned on the mounting posts 12. The through holes 22 align with the mounting holes 120. The clipping portion 36 of the cable clip 30 is located at a side of the circuit board 20. The fasteners 40 extend through the through holes 22 of the circuit board 20 to engage in the mounting holes 120. Thus, the circuit board 20 is tightly fastened to the bottom plate 10. The bottom of the main body 32 resists against the bottom plate 10, the top of the mounting portion 34 resists against the bottom of the circuit board 20. Thus, the cable clip 30 is tightly clamped between the circuit board 20 and the bottom plate 10.

It is believed that the present embodiment and its advantages will be understood from the foregoing description, and it will be apparent that various changes may be made thereto without departing from the spirit and scope of the description or sacrificing all of their material advantages, the examples hereinbefore described merely being exemplary embodiments.

What is claimed is:

1. An enclosure comprising:
a bottom plate comprising a plurality of mounting posts perpendicularly extending from the bottom plate, wherein each mounting post axially defines a mounting hole;
a cable clip comprising a main body, a mounting portion perpendicularly extending from a first end of the main body, and a clipping portion extending from a second end of the main body to bind cables, wherein the mounting portion defines a first though hole extending through the main body, through which a corresponding one of the mounting posts extends;
a circuit board connect to the cables, and defining a plurality of second through holes corresponding to the mounting holes, wherein the circuit board supported on the mounting posts, with the second through holes aligning with the mounting holes; and
a plurality of fasteners extending through the second through holes to engage in the mounting holes to fasten the circuit board to the bottom plate, wherein the mounting portion of the cable clip is clamped between the circuit board and the bottom plate, and the clipping portion is located at a side of the circuit board.

2. The enclosure of claim 1, wherein the mounting portion is substantially cylinder-shaped, and axially defines the first through hole.

3. The enclosure of claim 2, wherein the sum of the thickness of the main body and the height of the mounting portion is substantially equal to the height of the corresponding mounting post, the bottom of the main body resists against the bottom plate, and the top of the mounting portion resists against the bottom of the circuit board, to make the cable clip be clamped between the circuit board and the bottom plate.

4. The enclosure of claim 1, wherein the clipping portion comprises two parallel first limiting pieces extending up from the second end of the main body, and two second limiting pieces each slantingly extending down from a top of the corresponding first limiting piece toward the other first limiting piece, the first limiting pieces and the second limiting pieces bound a clipping space to receive the cables.

5. The enclosure of claim 4, wherein a cable channel is defined between the second limiting pieces, communicating with the clipping space.

6. A cable clip mountable in an enclosure of an electronic device to bind cables connected to a circuit board, the cable clip comprising:
a main body to be supported a bottom plate of the enclosure;
a mounting portion extending up from a first end of the main body; and
a clipping portion extending up from a second end of the main body to bind the cables;
wherein the mounting portion defines a first though hole through which a mounting post of the bottom plate for supporting the circuit board extends.

7. The cable clip of claim 6, wherein the clipping portion comprises two opposite first limiting pieces extending up from the second end of the main body, and two second limiting pieces each extending from a top of the corresponding first limiting piece toward the other first limiting piece, the first limiting pieces and the second limiting pieces bound a clipping space to receive the cables.

8. The cable clip of claim 7, wherein a cable channel is defined between the second limiting pieces, communicating with the clipping space, through which the cables enter the clipping space.
